(19) United States
(12) Patent Application Publication
(10) Pub. No.: US 2010/0014251 A1
(43) Pub. Date: Jan. 21, 2010

(54) Multidimensional Thermal Management Device for an Integrated Circuit Chip

(75) Inventor: Gamal Refai-Ahmed, Markham (CA)

Correspondence Address: ADVANCED MICRO DEVICES, INC.;C/O VEDDER PRICE P.C., 222 N.LASALLE STREET, CHICAGO, IL, 60601, US

(73) Assignee: Advanced Micro Devices, Inc., Sunnyvale, CA (US)

(21) Appl. No.: 12/173,478

(22) Filed: Jul. 15, 2008

(51) Int. Cl. H05K 7/20

(52) U.S. Cl. 361/701

(57) ABSTRACT

The present invention generally relates to a multidimensional thermal management device for an integrated circuit chip, and more particularly, to thermal management devices with a synthetic jet ejector adapted to operate along a hollow fin and a fin with cross-flow heat exchanger tubes. A thermal management device 50, a new circuit assembly 100 equipped with the new thermal management device 50, and a new guide for a synthetic jet ejector 20 for adapting the synthetic jet ejector technology to the new thermal management device 50 and associated circuit assembly 100 are disclosed.

### FIELD OF THE INVENTION

The present invention generally relates to a multidimensional thermal management device for an integrated circuit chip, and more particularly, to thermal management devices with a synthetic jet ejector adapted to operate along a hollow fin and a fin with cross-flow heat exchanger tubes.

### BACKGROUND OF THE INVENTION

Electronic components such as integrated circuit chips produce heat during operation. These components may be mounted on circuit substrates to form circuit assemblies. In turn, these circuit assemblies are placed on breadboards, or circuit boards where they are used. These assemblies are often confined within casings where convective air cooling is hampered. Improved cooling solutions are necessary for certain electronic components to maintain operational temperatures below a critical level, which, if reached, may damage the electronic component or reduce its efficiency or effectiveness.

Thermal management devices are mounted to the electronic component to be cooled and drain heat from the component by heat conduction, heat convection or heat irradiation. Ultimately, the heat from the component is drained to the surrounding air in a forced or natural flow of air. Various cooling solutions are known in the art. For example, a heat sink typically made of copper or aluminum can be attached to the outer surface of the electronic component with a thermal adhesive. The heat generated by the electronic component is then drained from the electronic component onto a colder heat sink by conduction. The conductive adhesive may be a thermal conductor that allows for heat transfer while offering some degree of resistance to the heat flux. The heat sink in turn transfers the heat to the surrounding air via natural or forced convection. One forced convection method includes the use of an air mover placed near or on a thinned walled series of parallel fins to increase the air flow near over the heat sink. Another forced convection method includes cooling the air itself using an air-cooling system that forces movement of the convective structure within the air.

Known conductive and convective air-cooling methods, however, fail to provide adequate heat removal for certain electronic devices that use intensive heat generating components or require intense local cooling. In electronic devices, components may require cooling to lower surface temperatures to maintain the component efficiency. The surface of components may also heat unevenly, creating hot spots that, unless cooled locally, reduce the overall efficiency of the thermal management device by reducing the average temperature difference between the component surface and the device before the component surface temperature reaches a critical level. Improved efficiency of new thermal management devices for small heating components used in electronic devices is limited where the internal space between the various components is of known and recognized usefulness.

One method of cooling single wall heat fins is to use synthetic jet ejectors, a technology described in U.S. Pat. No. 5,758,823, with a series of jets aligned along a first orientation to direct small jets of cooling air between two consecutive fins to improve convective coefficients. What is unknown are improved thermal management devices capable of utilizing synthetic jet ejector technology in connection with other types of cooling structures.

### BRIEF DESCRIPTION OF THE DRAWINGS

The features of the present disclosure are believed to be novel and are set forth with particularity in the appended claims. The disclosure may best be understood by reference to the following description taken in conjunction with the accompanying drawings, and the figures that employ like reference numerals identify like elements.

FIG. 1 is a three-dimensional partly exploded view of a circuit assembly with thermal management device with an air mover over a heat distribution core of a possible embodiment in accordance with the teachings of the present disclosure.

FIG. 2 is a three-dimensional synthetic jet ejector and guide of FIG. 1 according to one embodiment of the present disclosure.

FIG. 3 is a three-dimensional heat exchanger with hollow fins and cross-flow heat exchanger tubes according to an embodiment of the present disclosure.

FIG. 4 is a cut view along line 4-4 as shown on FIG. 3 as an elevation view of a fin of the heat exchanger with hollow fins and cross-flow heat exchanger tubes according to an embodiment of the present disclosure.

FIG. 5 is a three-dimensional partial representation of a partly curved fin of the heat exchanger of FIG. 3 according to an embodiment of the present disclosure.

FIG. 6 is a partial view of part of fin of the heat changer with a exit port of a synthetic jet to illustrate a flow within the hollow fin in according to an embodiment of the present disclosure.

FIG. 7 is schematic representation of the different flows associated with the circuit assembly shown in FIG. 1.

FIG. 8 is a is a three-dimensional partly exploded view of a circuit assembly with thermal management device in accordance with another embodiment of the present disclosure.

### DETAILED DESCRIPTION

In the following detailed description, reference is made to the accompanying drawings that show, by way of illustration, embodiments of the disclosure, each centered around an improved thermal management device based synthetic jets technology used in conjunction with convective or conductive heat transfer technology. These embodiments are described with sufficient detail to enable one skilled in the art to practice the disclosure. It is understood that the various embodiments of the disclosure, although different, are not necessarily exclusive and can be combined differently because they show novel features. For example, a particular feature, structure, heat dissipation vehicle, or characteristic described in connection with one embodiment may be implemented within other embodiments without departing from the spirit and scope of the disclosure. In addition, it is understood that the location and arrangement of individual elements, such as geometrical parameters, within each disclosed embodiment may be modified without departing from the spirit and scope of the disclosure. Other variations will also be recognized by one of ordinary skill in the art. The following detailed description is, therefore, not to be taken in a limiting sense.

What is desired is a new thermal management device 50, a new circuit assembly 100 equipped with the new thermal management device 50, or a new guide for a fluid pumping device or more specifically a synthetic jet ejector 20 for adapting the synthetic jet ejector technology to the new thermal management device 50 and associated circuit assembly 100.

Broadly, heat transfers from a hot conductor to a colder conductor either by conduction, radiation, or through natural or forced convection of the movement of a fluid or gas over the surface of the conductor. This disclosures relates generally to an improved, thermal management device and circuit assembly capable of improved heat transfer using fluid pumping technology and more specifically synthetic jet technology, a technology capable of improving forced convection over selected parts of the heat conductor subject to conduction, natural or forced convection.

Many different parameters come into play when determining convective heat transfer of a body such as a thermal management device 50, for example, a higher external temperature, a colder temperature of the heat evacuation medium such as air over the external surface of the conductor, or a greater average temperature difference between the surface of the conductor and the heat evacuation medium. Other parameters include thermal inertia of the heat evacuation medium, the density, the velocity, and the orientation of the medium oven the external surface of the thermal management device 50.

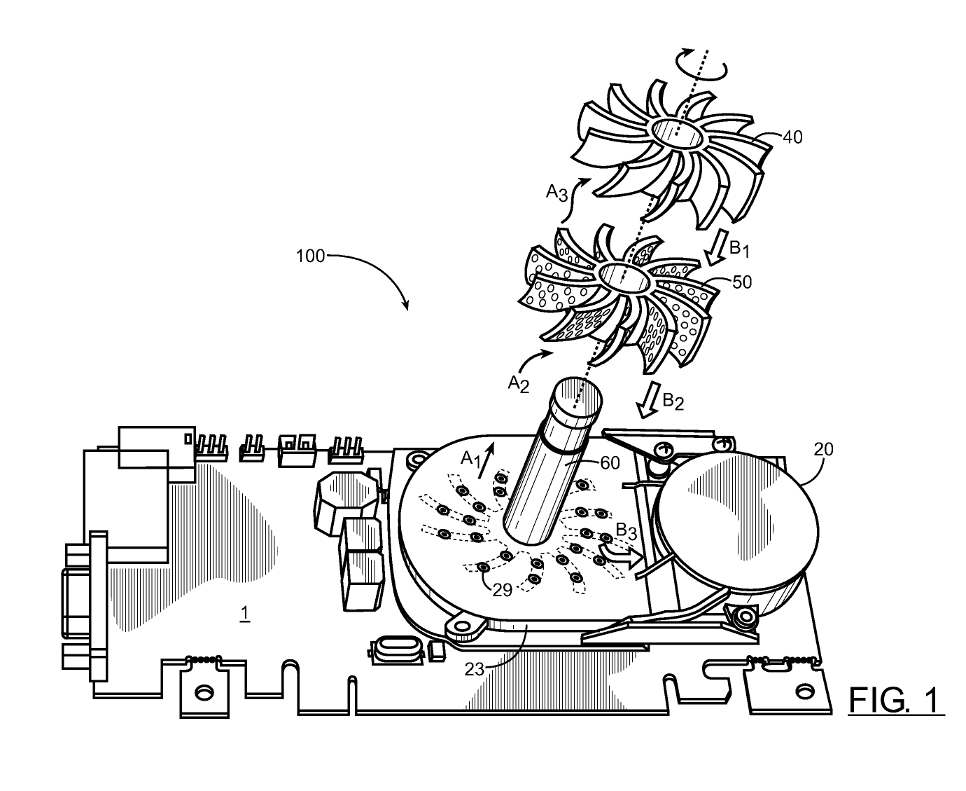

One method of improve convection is to use fluid movers such as air movers 40 as shown on FIG. 1. Fans, when rotating create a forced flow in their vicinity and once air is moved over the surface, greater cooling is achieved. Another method is to use a fluid pumping device such as a synthetic jet actuator to direct a flow of forced air over heat exchange fins. But unlike an air mover, the forced flow of synthetic jets (e.g., streams of fluid) is weaker but directional. What is needed is a new way of using synthetic jet actuation technology to improve thermal management devices 50.

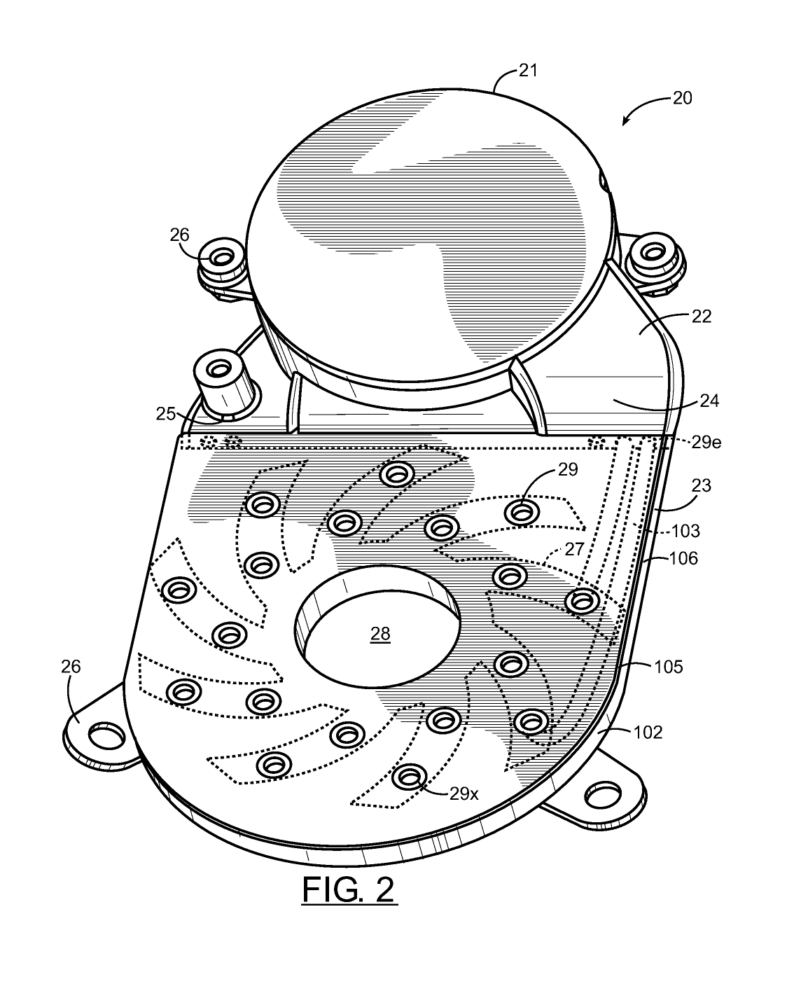

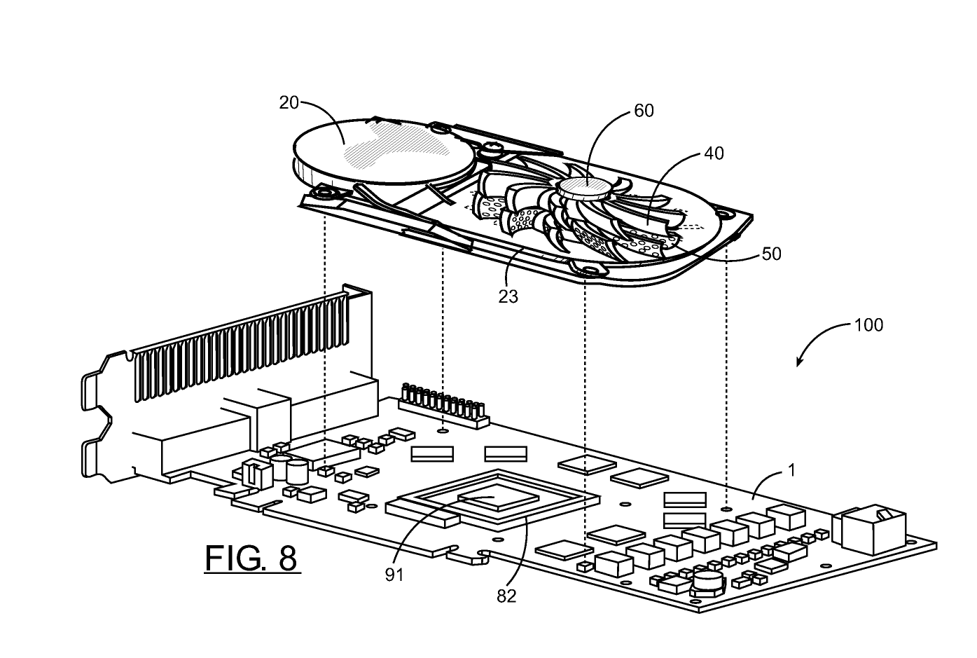

FIG. 2 shows a three-dimensional fluid pumping device such as a synthetic jet ejector 20 and guide 23. Synthetic jet engines 21 from the prior art direct a plurality of jets along a line 24 in a first orientation. These engines 21 at attached 26 to a board 1 on which they are mounted. Screws, tabs, or other types of fixation 25, 26 are used to mount the engine 21 to the board 1, or any other type of structure as shown on FIG. 8 for example, or any other types of applications where boards are equipped with a heating power source for any and all electronic application. While one type of fixation 25 is shown, what is contemplated is any fixation known in the art to place elements and components on a board, including but not limited to snap fits, tabs, clips, magnets, adhesives, or even slide locks.

A guide 23 for the synthetic jet ejector 20 with a plurality of synthetic jets 29 along a first orientation, includes a guide plate 102 with a plurality of grooves 103 each connected to an entry port 29e and an exit port 29x. The entry port 29e is adapted to receive a jet of the synthetic jet ejector 20 along the first orientation, and the exit port 29x adapted to release the jet 29 of the synthetic jet ejector 20 in a second orientation. FIG. 2 shows in one preferred embodiment, the first direction is perpendicular to the second direction. The plurality of jets 29 are placed along a pattern 27 corresponding to the different fins 51 of the thermal management device 50. A different configuration of thermal management device 50 requires the placement of the jets 29 at different positions. The plurality of exit ports 29x as shown are arranged on the guide 23 for adaptation with an inside surface 70 of a hollow fin 51 of a heat exchanger 50 defined by the inner surface 70 and an external surface 52. The guide 23 as shown on FIG. 2 includes an opening 28 where a heat distribution core 60 is used to distribute heat from a heat generating component 91 located below the guide 23 to the thermal management device 50 located above the guide 23.

In one embodiment, thin-walled heat exchange fins are paired into a single hollow fin 51 where a first convective flow A shown on FIGS. 1, 4-7 is directed in the hollow fin 51. A second convective flow B shown on FIGS. 1, 4-7 is located on the outside of the hollow fin 51. Further improvements to the convective exchange ratio occur when the first convective flow A and the second convective flow B are crossed to prevent cold air from acting on the same portion of the heat exchanger 50. When the first convective flow A is created in a first orientation (e.g., from the bottom to the top of a cavity such as a hollow fin 51), and the second convective flow B is created in a different orientation (e.g., from the top to the bottom of the hollow fin 51) either because of natural convection over the fin surface 52, or because of forced convection by the air mover 40 or any other type of device, greater heat exchange occurs.

In addition to this first contemplated cross flow between flows A and B, a cavity such as for example a hollow fin 51 may include a plurality of hollow tubes 54 for the passage of the heat evacuation medium in contact with the external surface 52 of the hollow fin from one side of the fin 51 to the next. The use of tubes 54 increases the contact area of the hollow fin 51 with the heat evacuation medium for both of the flows A and B. By increasing both the internal 70 and the external surface 52, the first convective flow A is placed in cross-flow configuration with the tubes 54 along a first direction perpendicular to the flow direction of the first convective flow A. In this configuration, the first convective flow A moves in one direction while part of the second convective flow B moves at 180 degrees and the remaining of the second convective flow B moves at 90 degrees. This effect is further improved when the hollow fin 51 is curved or the fins are placed upon a structure that creates a pressure difference between a frontal surface 53 of the hollow fin 51 and a back surface.

FIGS. 1-3 are directed to one contemplated embodiment of the thermal management device 100, and FIGS. 4-7 are directed to flow diagrams needed to illustrate how the different convective flows are distributed in relation with the first contemplated embodiment of the thermal management device 100. Disclosed is the principle of improved heat convection where the thermal management device 100 includes a heat exchanger 50 having a hollow fin 51 defined by an inner surface 70 and an external surface 52. A synthetic jet ejector 20 is adapted to direct a plurality of synthetic jets 29 over the inner surface 70 of the hollow fin 51. Either natural convection or forced convection is adapted to flow over the external surface 52.

Two types of flow arrows are shown on FIG. 1, a first type, also referred to as the first convective flow A where air or an heat exchange medium moves away from the synthetic jet ejector 20. Arrow Al shows the flow above the synthetic jets 29, arrow A2 shows the flow through the heat exchanger 50, and arrow A3 shows the flow over the heat exchanger. The use of small narrow arrows to illustrate the first convective flow A (A1, A2, A3) is simply a means to distinguish visually between the first convective flow A and the second convective flow B. FIG. 7 also illustrates these two convective flows in functional relationship with the different elements of the present disclosure.

FIGS. 4, 5, and 6 illustrate movement of the first convective flow A, and the second convective flow B around and inside of the hollow fins 51 of the heat exchanger 50. FIG. 4 shows how a synthetic jet 29 releases the first convective flow A5 that migrates through the hollow fin 51 away from a guide 23. The first convective flow moves up A6 through and around a series of tubes 54 shown as perpendicular to the first convective flow A. Finally, the flow is released at the top end 121 of the hollow fin where it is free to move unconfined by the hollow fin structure 51. Part of the secondary convective flow B5 passes in the tubes 54 and is then released on the back side of the hollow fin 51. A first flow shown as B6 moves through an upper tube 54, and a second flow shown as B7 moves through a lower tube 54. For example, in this given configuration, the tube 54 located at B6 has a lower surface temperature than tube 54 located at B7 because it is more distant from the guide 23. In addition, the first convective flow A will to the contrary be colder when it contacts the tube 54 at B7 than the flow A when it contacts the tube 54 at B6. As a consequence of the cumulative presence of heat exchange tubes 54 and hollow fins to funnel the first convective flow A in a cross flow configuration when compared to the second convective flow B, the overall heat homogenization is improved and the overall heat temperature difference for the purpose of convective heat calculation efficiency is also improved.

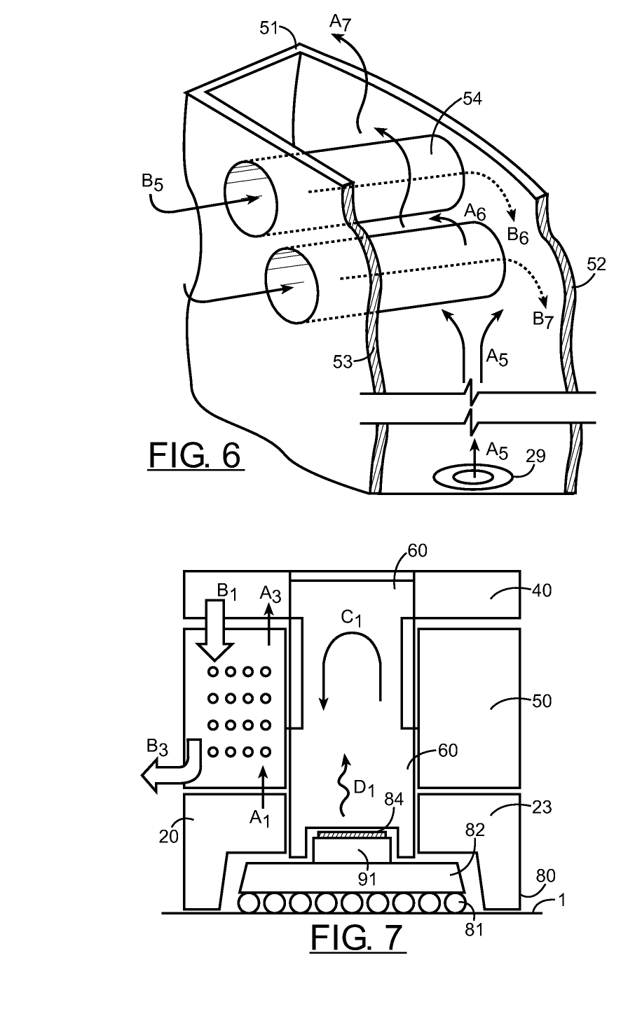

FIG. 5 is a configuration where tubes 54 are staggered between two successive rows or columns, what is also contemplated is a configuration where tubes 54 are also staggered between two successive fins. The second convective flow B illustrated as B5 is pushed on both sided of the hollow fin 51. Part of the secondary convective flow B8 is shown to remains on the front 53 of the hollow fin 51 while a second part illustrated by B6, and B7 will migrate from the front 53 to the back 52 through the tubes 54. FIG. 6 shows how the first convective flow A where tubes 54 are located within the hollow fin 51 will migrate around the different tubes A6, A7 to further improve contact flow between the first convective flow A and the external surface of the tubes 54.

Most of the geometric parameters, such as the width of the fin 51, the type of tubes 54 shown as cylindrical tubes, the thickness of the front 53 and back 52 walls of the hollow fin 51, the external curvature of the fin 51 on both the front 53 and the back 52 wall are only illustrative of the present embodiment and are given as the contemplated current best mode. The location of the synthetic jets 29 is also shown centered within the hollow fin 51. The placement of synthetic jets 29 at any orientation or configuration is contemplated as long as it creates a first convective flow A over the inner surface 70.

FIG. 7 shows a diagrammatic view of the circuit assembly where a board 1 includes a circuit substrate 82 where a heat generating element 91 is attached using normal conventional ways known to those of ordinary skill in the art, here shown as a support soldered on the board 1 using solder balls 81. In one embodiment, the heat generating element 91 is connected to the heat exchanger 50 via at least one electrically cooled layer for example made of nanowire technology 84. In another embodiment as shown in FIG. 7, the heat exchanger 50 comprises a heat distribution core 60 connected to the fins 51 at the surface 55 and is made of a thermal conductive material, this material being either copper, a copper bar or a heat pipe made of conductive material. In yet another embodiment, the cooled layer of nanowire technology 84 is adapted to thermally couple the heat generating element 91 and the heat distribution core 60. What is also contemplated is the use of localized technology, such as layer 84 at localized regions of the heat generating element 91 where heat creation is specifically high (i.e. hot spots).

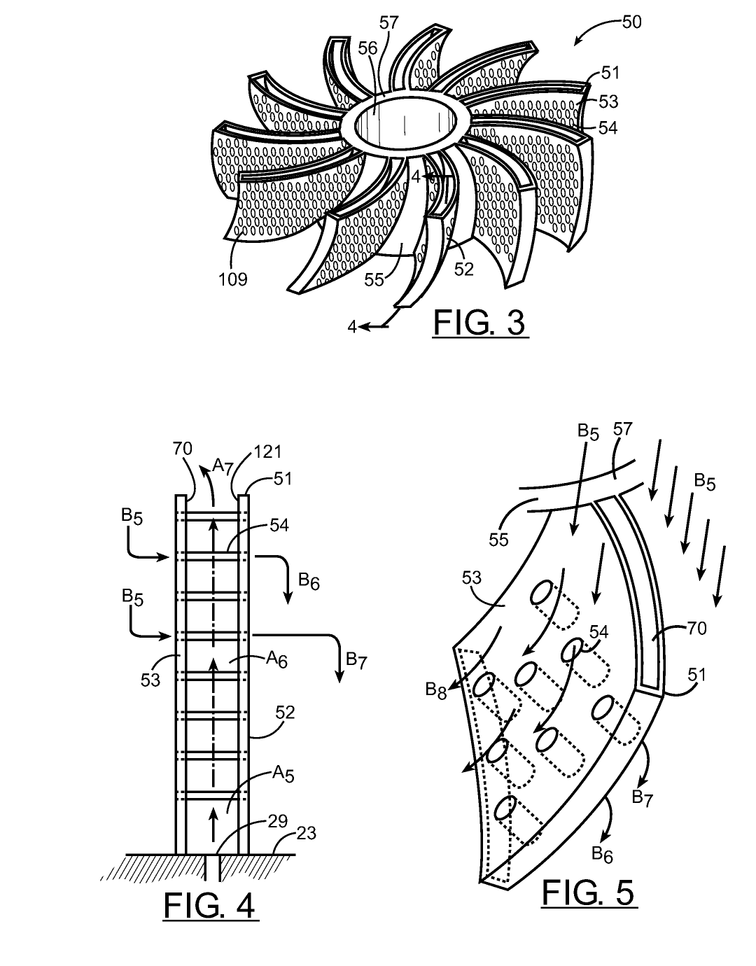

In the configuration as shown, since the fins 51 are in radial relationship with a center cylindrical core 60 in contact with an internal surface 56 as shown on FIG. 3. Heat transfer can be improved by accelerating heat transfer from one part of the core 60 to another part of the core 60 by using other technologies such as heat pipes. FIG. 7 illustrates as D1 the conductive heat transfer through the core 60 if, for example, a copper core is used. The arrow Cl illustrates the movement of water or other heat transfer dual phase liquid within a hollow core 60 to help distribute heat to the different portions of the core 60.

The core 60 is shown on FIG. 1 having a groove. The connection between the core 60 and the different elements in thermal connection therewith such as the mover 40, the heat exchanger 50, or the guide 23. In one embodiment, the heat distribution core 60 is thermally connected to a heat generating element 91 and includes a transfer agent that also can be shown by 84 as a layer of nanowires, or a multi-layer foil. The heat distribution core 60 is also thermally connected to the heat generating element 91 and includes a thermal interface created by the adjacent faces of the core 60 and the heat generating element 91 or, if an intermediate layer 84 is present between these surfaces, the thermal interface is created between the layer 84 and the heat generating element 91, and/or between the layer 84 and the core 60.

A thermal interface material (TIM), such as a grease, a paste, a solid, or a liquid can be added or used in place of, in addition to, or imbedded in, the layer 84 at the thermal interface. The thermal interface between two adjacent surfaces described above can also include at least one patterned surface, such as a surface with grooves or a large surface broken down in smaller surfaces in a matrix arrangement with grooves/angles or channels as known in the art in contact with the thermal interface material to create a dynamic resistance to the slow migration of the TIM over the thermal interface.

The invention is not limited to the particular details of the apparatus or method depicted and other modifications and applications may be contemplated. Further changes may be made in the above-described method and device without departing from the true spirit of the scope of the invention herein involved. It is intended, therefore, that the subject matter in the above depiction should be interpreted as illustrative, not in a limiting sense.

What is claimed is:

1. A thermal management device comprising: a heat exchanger with a cavity defined by an inner surface, and an external surface; and a fluid pumping device adapted to direct a plurality of jets over the inner surface.

2. The thermal management device of claim 1, wherein the cavity is a fin and the fluid pumping device is a synthetic jet ejector.

3. The thermal management device of claim 2, further comprising a mover adapted to direct a flow over the cavity.

4. The thermal management device of claim 2, wherein the fin comprises a plurality of cross-flow heat exchanger tubes.

5. The thermal management device of claim 4, wherein the tubes are staggered along rows and columns over the surface of the fin.

6. The thermal management device of claim 4, wherein the heat exchanger comprises a plurality of radially extending fins.

7. The thermal management device of claim 6, wherein the tubes are staggered between two successive fins.

8. The thermal management device of claim 2, wherein the heat exchanger comprises a heat distribution core thermally connected to the fin.

9. The thermal management device of claim 6, wherein the heat exchanger comprises a heat distribution core and wherein each of the plurality of fins are connected to the core.

10. The thermal management device of claim 8, wherein the heat distribution core is also thermally connected to a heat generating element and includes a transfer agent selected from the group consisting of: a layer of nanowires, and a multi-layer foil.

11. The thermal management device of claim 8, wherein the heat distribution core is also thermally connected to a heat generating element and includes a thermal interface and a thermal interface material selected from the group consisting of: a grease, a paste, a solid, or a liquid.

12. The thermal management device of claim 11, wherein the thermal interface includes at least one patterned surface with grooves in contact with the thermal interface material.

13. A circuit assembly comprising:
a circuit substrate;
a heat generating component adapted to the circuit substrate; and
a thermal management including a heat exchanger with a hollow fin defined by an inner surface, and an external surface, and a synthetic jet ejector adapted to direct a plurality of synthetic jets over the inner surface.

14. The circuit assembly of claim 13, wherein the fin comprises a plurality of cross-flow heat exchanger tubes across the hollow fin.

15. A guide for a synthetic jet ejector with a plurality of synthetic jets along a first orientation, comprising: a guide plate with a plurality of passages each connected to an entry port and an exit port, the entry port adapted to receive a jet of a synthetic jet ejector along the first orientation, and the exit port adapted to release the jet of the synthetic jet ejector in a second orientation.

16. The guide for a synthetic jet ejector of claim 15, wherein the second orientation is perpendicular to the first orientation.

17. The guide for a synthetic jet ejector of claim 16, wherein the plurality of exit ports are arranged on the guide for adaptation with an inside surface of a hollow fin of a heat exchanger defined by the inner surface, and an external surface.
